(19) United States
(12) Patent Application Publication
(10) Pub. No.: US 2024/0429061 A1
(43) Pub. Date: Dec. 26, 2024

(54) METHOD FOR MANUFACTURING PROCESSED SUBSTRATE

(71) Applicant: MERCK PATENT GMBH, DARMSTADT (DE)

(72) Inventors: MASANOBU HAYASHI, SHIZUOKA (JP); HIROYUKI AOKI, SHIZUOKA (JP)

(21) Appl. No.: 18/827,593

(22) Filed: Sep. 6, 2024

Related U.S. Application Data
(63) Continuation of application No. PCT/EP2023/055527, filed on Mar. 6, 2023.

(30) Foreign Application Priority Data
Mar. 8, 2022 (JP) 2022-035569

(51) Int. Cl. H01L 21/3105; H01L 21/02

(52) U.S. Cl. CPC H01L 21/31053; H01L 21/02118

(57) ABSTRACT

A method for manufacturing a processed substrate includes the following steps:
(a) applying a cured film forming composition on a substrate having grooves in an amount sufficient to fill grooves to form a composition layer; (b) removing the surplus part from the composition layer by scraping off using a separation member to form a substrate surface with improved flatness; and (c) heating the substrate to cure the composition layer in which the surplus part is removed.

### CROSS-REFERENCE TO RELATED APPLICATIONS

This application is a Continuation under 35 USC § 111 (a) of International Patent Application No. PCT/EP2023/055527, filed Mar. 6, 2023, which claims priority to the Foreign Application No. JP2022-035569 filed on Mar. 8, 2022. The entire contents of these applications are incorporated herein by reference in their entirety.

### BACKGROUND OF THE INVENTION

### Technical Field

The present invention relates to a method for manufacturing a processed substrate.

### Background Art

Electronic devices, particularly semiconductor devices, have multilayered wiring layers and the like due to high integration. In order to insulate each laminated layer when multilayering, a liquid composition is applied to form a coating film, which is then cured to form an insulating film. This film is required to be flat because further processing is performed. Planarization is performed, for example, by a method such as chemical mechanical polishing (CMP).

In planarization by CMP, differences in planarization characteristics may occur due to hardness and chemical properties, and it is inefficient for planarizing thick films. Therefore, as a new planarizing method, a method for physically cutting the formed cured film to a predetermined height has been proposed as disclosed in, for example, EP 2075825.

When a coating film is formed by filling the grooves with a liquid composition, if the grooves have a complicated structure or the grooves are deep, the planarization of the formed coating film becomes low and the film thickness tends to become uneven.

If the film thickness is uneven, film stress becomes uneven during heating for curing, cracks are likely to occur, and it becomes difficult to form a dense cured film.

### SUMMARY OF THE INVENTION

### Problems to be Solved by the Invention

The present inventors considered that there are still one or more problems that need improvement regarding the method for manufacturing a substrate having grooves in which a cured film is filled. For example, they include the following:

The planarity of the cured film formed is low; cracks occur; the density of the cured film formed is low; and the planarization method of the cured film is not efficient.

### Means for Solving the Problems

The method for manufacturing a processed substrate according to the present invention comprises the following steps:
(a) applying a cured film forming composition on a substrate having grooves in an amount sufficient to fill the grooves to form a composition layer;
(b) removing the surplus part from the composition layer by scraping off using a separation member to form a substrate surface with improved flatness; and
(c) heating the substrate to cure the composition layer in which the surplus part is removed.

The method for manufacturing an electronic device according to the present invention comprises the above method.

### Effects of the Invention

According to the invention, one or more of the following effects are provided.

The planarity of the cured film formed is high; the occurrence of cracks is suppressed; the density of the cured film formed is high; and the manufacturing process is efficient.

### BRIEF DESCRIPTION OF THE DRAWINGS

FIG. 1 is a conceptual diagram showing one embodiment of the composition layer before and after the surplus part is removed.

FIG. 2 is an electron microscope photograph of the state in which the composition is cured.

### DETAILED DESCRIPTION OF THE INVENTION

### Mode for Carrying Out the Invention

### Definitions

Unless otherwise specified in the present specification, the definitions and examples described below are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element. When a numerical range is indicated using “to” or “−”, it includes both endpoints and units thereof are common. For example, 5 to 25 mol % means 5 mol % or more and 25 mol % or less.

The alkyl means a group obtained by removing any one hydrogen from a linear, branched, or cyclic saturated hydrocarbon and includes a linear alkyl, branched alkyl or cycloalkyl and optionally includes a linear or branched alkyl in the cyclic structure as a side chain. The aryl means a group obtained by removing any one hydrogen from an aromatic hydrocarbon.

The descriptions such as “Cx-y”, “Cx-Cy” and “Cx” mean the number of carbons in a molecule or substituent. For example, C1-6 alkyl means an alkyl chain having 1 or more and 6 or less carbons (methyl, ethyl, propyl, butyl, pentyl, hexyl etc.).

When polymer has plural types of repeating units, these repeating units copolymerize. These copolymerization can be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent or another component.

Hereinafter, embodiments of the present invention are described in detail.

### Method for Manufacturing Processed Substrate

The method for manufacturing a processed substrate according to the present invention comprises the following steps:
(a) applying a cured film forming composition on a substrate having grooves in an amount sufficient to fill grooves to form a composition layer;
(b) removing the surplus part from the composition layer by scraping off using a separation member to form a substrate surface with improved flatness; and
(c) heating the substrate to cure the composition layer in which the surplus part is removed.

### Step (a)

Step (a) is a step of applying a cured film forming composition on a substrate having grooves in an amount sufficient to fill grooves to form a composition layer.

In the present invention, the substrate can be a single layer or a laminate. The shape of the groove is not particularly limited, but in the present invention, it is characterized in that it can easily fill into narrow grooves and a uniform cured film can be formed even inside the grooves. A substrate having grooves and holes having high aspect ratio is preferred. The shape of the groove is not particularly limited, and the cross section may be rectangular, forward tapered, reverse tapered, curved, or any other shape. Both ends of the groove can be open or closed.

Substrates having grooves include, for example, substrates for electronic devices comprising transistor devices, bit lines, capacitors, and the like. In the manufacture of such electronic devices, subsequently to steps, forming an insulating film between a transistor device and a bit line called PMD, between a transistor device and a capacitor, between a bit line and a capacitor, or between a capacitor and a metal wiring, forming an insulating film called IMD between plural metal wirings, and filling isolation trenches, a through-hole forming step through the filled material of fine grooves can be contained.

A cured film forming composition is applied on a substrate, and in the present invention, the cured film forming composition can be applied directly on the substrate, or can be applied on the substrate via one or more interlayers.

There are no particular restrictions on the method for coating the substrate, and conventional coating methods, such as spin coating method, dip coating method, spray coating method, transfer coating method and slit coating method, are included.

The preferred cured film forming compositions are described later.

A composition layer is formed by applying the cured film forming composition. If necessary, a drying step can be performed by spin drying, reduced pressure, or prebaking, but the drying step by spin drying is performed, preferably without a heating step at 150° C. or higher, more preferably without any heating step.

The amount that sufficiently fills the grooves of the substrate refers to a state, in which the grooves are filled with the cured film forming composition and the composition layer is also formed on the area of the substrate surface having no grooves.

### Step (b)

Step (b) is a step of removing the surplus part from the composition layer by scraping off using a separation member to form a substrate surface with improved flatness.

In step (b), the scraping off is performed by pressing and moving the separation member against the substrate. In one preferred embodiment, the scraping off is performed by moving the separation member parallel to the main plane of the substrate, preferably by rotating the separation member in a horizontal plane in a state that the substrate is set stationary. The scraping off can also be performed by fixing the separation member and rotating the substrate, or by making both move. It is also possible to use an apparatus for planing the substrate surface, or the like.

The separation member has, for example, a blade portion, and the material of the blade portion is not particularly limited as long as it has appropriate hardness, and stainless steel, resin or the like can be used.

By adjusting the hardness of the blade portion of the separation member and the pressing force (down force), the amount of the surplus part to be scraped off can be adjusted. When a large amount of the composition remains on the substrate surface after scraping off, the thickness of the composition layer tends to vary, that is, the film thickness difference tends to increase, so that the hardness and pressing force of the blade portion can be adjusted for getting a desired film thickness difference. More specifically describing, the film thickness difference refers to the difference between the highest point and the lowest point of the composition layer when the cross section is observed by cutting in the direction perpendicular to the substrate surface.

The film thickness difference after the scraping off is preferably 2 μm or less, more preferably 1 μm or less.

The composition layer before the scraping off in step (b) is in a state before curing, and at this time, the elastic modulus of the composition layer is preferably 0.5 to 4.5 GPa, more preferably 0.7 to 4.0 GPa. Being within this range, more uniform scraping can be performed, the blade portion is less likely to be damaged, and the scraping off can be performed more stably.

Prior to step (b), the composition layer can be heated to facilitate processing, but even in such a case, it is preferable not to include step of heating the substrate on which the composition layer is formed at 100° C. or higher.

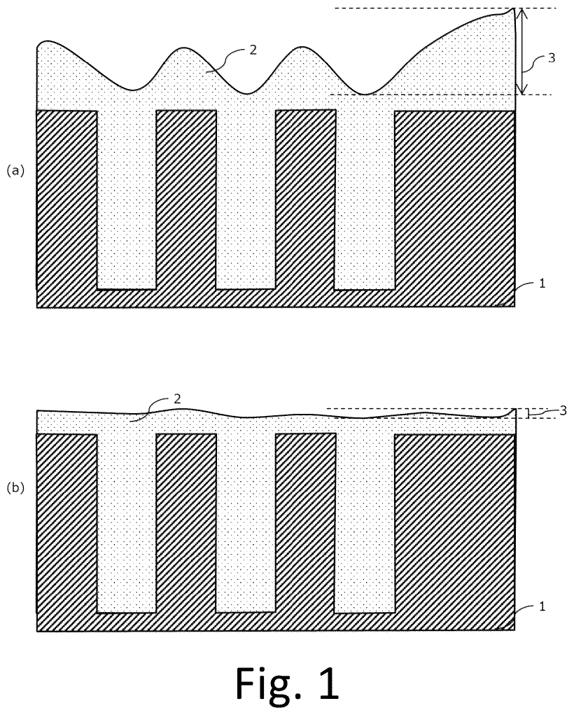

FIG. 1(a) is a conceptual diagram of a state in which the composition layer is formed in step (a) in the area having grooves. The composition layer 2 is formed on the substrate 1 having grooves, and the film thickness difference 3 is in a state of large. FIG. 1(b) shows a conceptual diagram of a state of the composition layer after the scraping off in step (b). The film thickness difference is small.

### Step (c)

Step (c) is a step of heating the substrate to cure the composition layer in which the surplus part is removed. The heating temperature in this step is not particularly limited as long as it is a temperature that the composition layer is cured. In order to accelerate the curing reaction and obtain a film that is sufficiently cured, the curing temperature is preferably 200° C. or higher, more preferably 300 to 1,000° C. The heating time is not particularly limited, preferably 1 minute to 10 hours, more preferably 1 to 180 minutes. The atmosphere at the time of curing varies depending on the composition used but is preferably a steam atmosphere or a nitrogen atmosphere. The curing process can be divided into two or more stages (more preferably three or more stages). For example, it can be first heated at a low temperature (for example, a temperature range of 200 to 400° C.) in an atmosphere containing water vapor, thereafter heated at a relatively low temperature (for example, a temperature range of 300 to 600° C.) in an atmosphere containing water vapor, and heated at a higher temperature (for example, 400 to 1,000° C.) in an atmosphere containing no water vapor.

It is also preferable to perform pre-baking to remove the solvent between step (b) and the heating for curing in step (c).

The elastic modulus of the composition layer cured in step (c) is preferably 8.0 to 80 GPa, more preferably 8.0 to 78 GPa.

In general, if the composition layer is cured in a state that it has a large film thickness difference, the influence of heat shrinkage during heating at the time of curing increases, and cracks tend to occur. In the present invention, the film thickness difference is reduced by the scraping off before the composition layer is cured. It can be thought that this suppresses the occurrence of cracks during curing, thereby obtaining a cured film with good film quality.

It is also preferable to further combine a chemical mechanical polishing step after step (c). In general, it is considered inappropriate to perform the chemical mechanical polishing on materials having soft film properties. This is because the film can be scratched or the abrasive grains can be bitten into the film during polishing. Due to the cured film state after step (c), a chemical mechanical polishing step can be applied, and by this application, the flatness can be further improved and a desired film thickness can be obtained. In the present invention, when planarizing by chemical mechanical polishing, the thickness of the composition layer is relatively thin due to step (b), so that it is easy to planarize by the chemical mechanical polishing.

The method for manufacturing an electronic device according to the present invention comprises the above-mentioned method. The electronic device is preferably a semiconductor device.

### Cured Film Forming Composition

The cured film forming composition (hereinafter referred to as the composition) used in the present invention is not particularly limited as long as it contains a component capable of forming a cured film.

The viscosity of the cured film forming composition is preferably 1.30 to 1.60 mPa·s, more preferably 1.33 to 1.60 mPa·s, further preferably 1.35 to 1.55 mPa·s as measured by a capillary viscometer at 25° C.

The component capable of forming a cured film can be a polymer, a polymerizable monomer component, or a mixture thereof. The composition according to the present invention preferably contains a polymer, and as the polymer, an epoxy-based polymer, an acrylic polymer, a silicon-containing polymer, and the like are included, and a silicon-containing polymer is more preferable.

In a preferred embodiment, the composition used in the present invention is a siliceous film forming composition.

In a preferred embodiment of the present invention, the composition used in the present invention comprises a silicon-containing polymer selected from the group consisting of polysilazane, polycarbosilazane, polysiloxane and polysiloxazane.

The mass average molecular weight of the silicon-containing polymer is preferably 1,000 to 30,000, more preferably 1,200 to 28,000, further preferably 1,500 to 25,000. In the present invention, the mass average molecular weight means a mass average molecular weight in terms of polystyrene, which can be measured by the gel permeation chromatography based on polystyrene. The same is applied to the other polymers.

The content of the silicon-containing polymer is preferably 10 to 100 mass %, more preferably 15 to 85 mass %, based on the total mass of the composition.

### Polysilazane

The structure of the polysilazane used in the present invention is not particularly limited, and any polysilazane can be freely selected depending on the purpose. The polysilazane has a Si—N bond as a main skeleton, can be either an inorganic compound or an organic compound, and can have a linear, branched, or partially cyclic structure.

Preferably, the polysilazane contains 20 or more, preferably 20 to 350, repeating units selected from the group consisting of the following formulae (1-i) to (1-vi). It is preferable that each repeating unit is directly bonded without intervening repeating units other than (1-i) to (1-vi). R1a to R1i are each independently hydrogen or C1-4 alkyl.

More preferably, the polysilazane used in the present invention is perhydropolysilazane (hereinafter referred to as PHPS). PHPS is a silicon-containing polymer comprising Si—N bonds as repeating units and consisting only of Si, N and H. In this PHPS, except Si—N bond, all elements binding to Si or N are H and any other elements such as carbon or oxygen are not substantially contained. The simplest structure of the perhydropolysilazane is a chain structure having a repeating unit of the following formula:

The structure of PHPS is not limited as long as it contains Si—N bonds as the repeating unit and is a silicon-containing polymer consisting only of Si, N and H, and can take various structures other than those exemplified above. PHPS preferably is one having a cyclic structure or a crosslinked structure, particularly a crosslinked structure.

The mass average molecular weight of the polysilazane is preferably 1,200 to 28,000, more preferably 1,500 to 25,000, from the viewpoint of solubility in solvents and reactivity.

### Polycarbosilazane

The structure of the polycarbosilazane used in the present invention is not particularly limited, and any polycarbosilazane can be freely selected depending on the purpose. The polycarbosilazane has a C—Si—N structure as a main skeleton, and preferably comprises a repeating unit represented by the following formula (2-i) and a repeating unit represented by the following formula (2-ii),
wherein,
R2a, R2b and R2c are each independently a single bond, hydrogen, or C1-4 alkyl, preferably a single bond or hydrogen.
R2d, R2e and R2f are each independently a single bond or hydrogen.

Provided that, when R2a, R2b, R2d and R2e are single bonds, they are bonded to N contained in other repeating units, and when R2c and R2f are single bonds, they are bonded to Si contained in other repeating units. n and m are each independently 1 to 3, preferably 1 or 2, more preferably 1.

The polycarbosilazane is preferably polyperhydro-carbosilazane. The polyperhydrocarbosilazane has R2a, R2b and R2c each being a single bond or hydrogen, and has no hydrocarbon groups other than (CH2)n and (CH2)m in the formula (2-i).

The terminal group of the polycarbosilazane is preferably —SiH3.

The polycarbosilazane according to the present invention preferably consists substantially of the repeating unit represented by the formula (2-i) and the repeating unit represented by the formula (2-ii). In the present invention, “substantially” means that 95 mass % or more of all structural units contained in the polycarbosilazane are the repeating unit represented by the formula (2-i) and the repeating unit represented by the formula (2-ii). More preferably, the polycarbo-silazane contains no repeating units other than the repeating unit represented by the formula (2-i) and the repeating unit represented by the formula (2-ii).

The mass average molecular weight of the polycarbosilazane according to the present invention is preferably large in order to prevent vaporization of low-molecular-weight components and suppress changes in volume when filled in fine trenches. On the other hand, a low viscosity is preferred for good coatability, and good filling in trenches with high aspect ratio. For these reasons, the mass average molecular weight of the polycarbosilazane is preferably 1,200 to 28,000, more preferably 1,500 to 25,000.

### Polysiloxane

The structure of the polysiloxane used in the present invention is not particularly limited, and any polysiloxane can be freely selected depending on the purpose. Depending on the number of oxygen atoms bonded to a silicon atom, the skeleton structure of a polysiloxane can be classified into a silicone skeleton (the number of oxygen atoms bonded to a silicon atom is 2), a silsesquioxane skeleton (the number of oxygen atoms bonded to a silicon atom is 3) and a silica skeleton (the number of oxygen atoms bonded to a silicon atom is 4). In the present invention, any of these can be used. The polysiloxane molecule can contain a plurality of combinations of any of these skeleton structures.

Preferably, the polysiloxane used in the present invention comprises a repeating unit represented by the following formula (3-i).

The formula (3-i) is as follows:
wherein,
R3a is hydrogen, a mono- to trivalent, linear, branched or cyclic, saturated or unsaturated, C1-30 aliphatic hydrocarbon group, or a mono- to trivalent, C6-30 aromatic hydrocarbon group, preferably hydrogen, linear, branched or cyclic, C1-6 alkyl, or C6-10 aryl, more preferably hydrogen, methyl, ethyl or phenyl, further preferably methyl.

The aliphatic hydrocarbon group and the aromatic hydrocarbon group are each unsubstituted or substituted with fluorine, hydroxy or C1-8 alkoxy, in the aliphatic hydrocarbon group and the aromatic hydrocarbon group, methylene is not replaced, or one or more methylene are replaced with oxy, imide or carbonyl, provided that R3a is neither hydroxy nor alkoxy, and when R3a is divalent or trivalent, R3a connects each Si contained in a plurality of repeating units.

In the formula (3-i), when R3a is a monovalent group, examples of R3a include, in addition to hydrogen, (i) alkyl such as methyl, ethyl, propyl, butyl, pentyl, hexyl, heptyl, octyl and decyl, (ii) aryl such as phenyl, tolyl and benzyl, (iii) fluoroalkyl such as trifluoromethyl, 2,2,2-trifluoroethyl and 3,3,3-trifluoropropyl, (iv) fluoroaryl, (v) cycloalkyl such as cyclohexyl, (vi) nitrogen-containing groups having an amino or imide structure such as isocyanates and aminos, and (vii) oxygen-containing groups having an epoxy structure such as glycidyl, or an acryloyl structure or methacryloyl structure. Preferred are methyl, ethyl, propyl, butyl, pentyl, hexyl, phenyl, tolyl, glycidyl and isocyanate. As the fluoroalkyl, perfluoroalkyl, particularly trifluoro-methyl and pentafluoroethyl are preferable. It is preferable that R3a is methyl because the raw material is easily available, the film hardness after curing is high, and the cured film has high chemical resistance. Further, it is also preferable that R3a is phenyl because solubility of the polysiloxane in solvents is increased and the cured film becomes less likely to crack.

When R3a is a divalent or trivalent group, R3a is preferably (i) a group obtained by removing two or three hydrogen from alkane such as methane, ethane, propane, butane, pentane, hexane, heptane, octane and decane, (ii) a group obtained by removing two or three hydrogen from cycloalkane such as cycloheptane, cyclohexane and cyclooctane, (iii) a group obtained by removing two or three hydrogen from an aromatic compound composed only of a hydrocarbon such as benzene and naphthalene, and (iv) a group obtained by removing two or three hydrogen from a nitrogen- and/or oxygen-containing alicyclic hydrocarbon compound containing an amino group, an imino group and/or a carbonyl group, such as piperidine, pyrrolidine and isocyanurate. In order to improve pattern sagging and increase adhesion to the substrate, being (iv) is more preferable.

The number of the repeating units represented by the formula (3-i) is preferably 1% or more, more preferably 20% or more, based on the total number of the repeating units contained in the polysiloxane molecule. Since the high compounding ratio of the repeating unit represented by the formula (3-i) causes deterioration of the electrical characteristics of the cured film, decrease of the adhesion of the cured film to the contact film and decrease of the hardness of the cured film, scratches of the film surface likely occurs. Therefore, the number of the repeating units represented by the formula (3-i) is preferably 95% or less, more preferably 90% or less, based on the total number of the repeating units of the polysiloxane.

The polysiloxane used in the present invention preferably further contains a repeating unit represented by the following formula (3-ii) in addition to the repeating unit represented by the formula (3-i).

The number of the repeating units represented by the formula (3-ii) is preferably 8% or more, more preferably 10 to 99%, further preferably 10 to 80%, based on the total number of the repeating units contained in the polysiloxane molecule. Since the high containing ratio of the repeating unit represented by the formula (3-ii) causes decrease of the compatibility with solvents or additives and increase of the film stress, cracks likely occurs. And the low containing ratio thereof causes decrease of hardness of the cured film.

The polysiloxane used in the present invention can comprise repeating units other than the above, but the number thereof is preferably 20% or less, more preferably 10% or less, based on the total number of the repeating units contained in the polysiloxane molecule. It is also a preferred embodiment of the present invention that it contains no repeating units other than the above.

The polysiloxane used in the present invention preferably has silanol at the end. Silanol means one in which an OH group is directly bonded to a Si skeleton, and it is one in which hydroxy is directly bonded to a silicon atom in a polysiloxane containing the above-mentioned repeating unit or the like. That is, silanol is composed by binding —O0.5H with —O0.5- of the above formula.

The mass average molecular weight of the polysiloxane used in the present invention is preferably 1,000 to 30,000, more preferably 1,200 to 28,000, further preferably 1,500 to 25,000.

### Polysiloxazane

The structure of the polysiloxazane used in the present invention is not particularly limited, and any polysiloxazane can be freely selected depending on the purpose. The polysiloxazane has a siloxane bond in the polysilazane main skeleton, and preferably comprises a repeating unit represented by the following formula (4-i) and a repeating unit represented by the following formula (4-ii).

That is a siloxazane compound having repeating units represented below:
(wherein, R4a, R4b, R4c, R4d and R4e are each independently a hydrogen atom, an alkyl group, an alkenyl group, a cycloalkyl group or an aryl group, at least one of R4a and R4b is a hydrogen atom, and at least one of R4d and R4e is a hydrogen atom),
which is characterized by the following:
in the siloxazane compound, the ratio of O atoms to the total number of O atoms and N atoms is 5% or more and 25% or less, and in the spectrum of the siloxazane compound obtained by 29Si-NMR based on the inverse gate decoupling method, the ratio of the area of the peak detected at −75 ppm to −90 ppm to the area of the peak detected at −25 ppm to −55 ppm is 4.0% or less.

The mass average molecular weight of the polysiloxazane according to the present invention is preferably large in order to prevent vaporization of low-molecular-weight components and suppress changes in volume when filled in fine trenches. On the other hand, a low viscosity is preferred for good coatability, and good filling even in trenches with high aspect ratio. For these reasons, the mass average molecular weight of the polysiloxazane is preferably 1,200 to 28,000, more preferably 1,500 to 25,000.

### Solvent

The composition used in the present invention can comprise a solvent. This solvent is selected from those that uniformly dissolve or disperse each component contained in the composition. The solvent includes, for example, ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates, such as propylene glycol monomethyl ether acetate (PGMEA), propylene glycol monoethyl ether acetate and propylene glycol monopropyl ether acetate; aromatic hydrocarbons, such as benzene, toluene, xylene and mesitylene; ethers, such as dipropyl ether, dibutyl ether and anisole; ketones, such as methyl ethyl ketone, acetone, methyl amyl ketone, methyl isobutyl ketone and cyclohexanone; alcohols, such as isopropanol and propanediol; and alicyclic hydrocarbons, such as cyclooctane and decalin. Xylene, dibutyl ether and propylene glycol monomethyl ether are preferred.

These solvents can be used alone or in combination of any two or more. The content of the solvent is preferably 1 to 96 mass %, more preferably 20 to 85 mass %, based on the total mass of the composition.

The composition used in the present invention can be combined with further optional components as necessary. The optional component includes, for example, surfactants. The content of the optional components excluding the solvent in the entire composition is preferably 10 mass % or less, more preferably 5 mass % or less, based on the total mass.

Hereinafter, the present invention is described with reference to Examples. These Examples are for explanation and do not intend to limit the scope of the present invention.

The synthesis and composition preparation processes in the following Examples and Comparative Examples are carried out in a low humidity state controlled at a dew point temperature of −30.0° C. or lower.

In the following Examples, the mass average molecular weight (Mw) is measured by the gel permeation chromatography (GPC) based on polystyrene. GPC is measured using Alliance (trademark) e2695 type high-speed GPC system (Nihon Waters K.K.) and an organic solvent-based GPC column Shodex KF-805 L (Showa Denko K.K.). The measurement is conducted using monodispersed polystyrene as a standard sample and chloroform as an eluent, under the measuring conditions of a flow rate of 0.6 ml/min and a column temperature of 40° C., and then Mw is calculated as a relative molecular weight to the standard sample.

### Preparation of Polysilazane-Containing Composition A

After replacing the inside of a 10 L reaction vessel equipped with a cooling condenser, a mechanical stirrer and a temperature controller with dry nitrogen, 7,500 ml of dry pyridine is added into the reaction vessel and it is cooled to −3° C. 500 g of dichlorosilane is added to form a white solid adduct (SiH2Cl2·2C5H5N). After confirming that the reaction mixture is cooled to −3° C. or lower, 350 g of ammonia is slowly introduced into it while stirring. Subsequently, after continuing to stir for 30 minutes, dry nitrogen is bubbled through the liquid layer for 30 minutes to remove excess ammonia. The resulting slurry product is subjected to pressure filtration using a Teflon (registered trademark) 0.2 μm filter under a dry nitrogen atmosphere to obtain 6,000 ml of a filtrate. Pyridine is distilled off using an evaporator, and xylene is added to obtain a 39.8 mass % polysilazane intermediate xylene solution. 4,710 g of dry pyridine, 150 g of dry xylene and 1,650 g of the 39.8 mass % polysilazane intermediate xylene solution obtained above are charged, and they are stirred to be uniform while bubbling nitrogen gas at 0.5 NL/min. Subsequently, a reforming reaction is carried out at 110° C. for 10.0 hours to obtain a 21.0 mass % polysilazane-containing composition A (hereinafter referred to as Composition A). The resulting polysilazane has a Mw of 8,200.

### Preparation of Polycarbosilazane-Containing Composition B

After replacing the inside of a 1 L reaction vessel equipped with a cooling condenser, a mechanical stirrer and a temperature controller with dry nitrogen, 500 ml of dry pyridine is added into the reaction vessel and it is cooled to −3° C. 9.67 g of dichlorosilane and 4.33 g of 1,1,3,3-tetrachloro-1,3-disilacyclobutane are added. After confirming that the reaction mixture is cooled to 0° C. or lower, 10.3 g of ammonia is slowly introduced into it while stirring. Subsequently, after continuing to stir for 30 minutes, dry nitrogen is bubbled through the liquid layer for 30 minutes to remove excess ammonia. The resulting slurry product is subjected to pressure filtration using a Teflon (registered trademark) 0.2 μm filter under a dry nitrogen atmosphere to obtain 400 ml of filtrate. After distilling off pyridine from the filtrate, xylene is added to obtain a 21.5 mass % of polycarbosilazane-containing composition B (hereinafter referred to as Composition B). The polycarbosilazane obtained has a Mw of 8,050.

### Preparation of Polysiloxane-Containing Composition C

32.5 g of a 40 mass % tetra-n-butylammonium hydroxide (TBAH) aqueous solution and 308 ml of 2-methoxypropanol (PGME) are charged into a 2 L flask equipped with a stirrer, a thermometer, and a condenser. Then, a mixed solution of 19.6 g of methyltrimethoxy-silane and 9.2 g of tetramethoxysilane is prepared in a dropping funnel. The mixed solution is dropped into the flask and the resultant is stirred at 80° C. for 2 hours. After cooling to room temperature and adding 500 ml of normal propyl acetate (n-PA), 1.1 equivalents to TBAH of 3 mass % maleic acid aqueous solution is added, and the mixture is stirred to neutralize for 1 hour. 500 ml of n-PA and 250 ml of water are added to the neutralized liquid, the reaction solution is separated into two layers, the resulting organic layer is washed three times with 250 cc of water and concentrated under reduced pressure to remove water and solvent, and PGME is added, thereby obtaining a 19.8 mass % of polysiloxane-containing composition C (hereinafter referred to as Composition C). The resulting polysiloxane has a Mw of 7,800.

### Preparation of Polysiloxazane-Containing Composition D

After replacing the inside of a 10 L reaction vessel equipped with a cooling condenser, a mechanical stirrer and a temperature controller with dry nitrogen, 2,800 g of dry pyridine and 400 g of a 39.8 mass % polysilazane intermediate xylene solution are charged and the mixed solution is cooled to −5° C. while stirring. A water-containing pyridine, in which 6 g of pure water is dissolved in 1,000 g of dry pyridine, is added dropwise over 3 hours to the mixed solution cooled to −5° C. while stirring. After dropping, the solution is allowed to return to room temperature and stirred for an additional hour. After pyridine is distilled off, xylene is added to obtain a 20.2 mass % polysiloxazane-containing composition D (hereinafter referred to as Composition D). The resulting polysiloxazane has a Mw of 5,600.

### Examples 1 and 2

Compositions A and B are each dropped on a silicon wafer (8 inches) having a pattern (grooves of width: 2 μm, length: 20 μm and depth: 14 μm) and spin-coated at a rotation speed of 100 rpm to form a coating film. The formed coating film is made thick in the area having no grooves and it is not flat. Scraping off is carried out. After that, a separation member having a 10 cm width formed by a fragment of a silicon wafer is vertically pressed at 9.8 N against the silicon wafer on which a coating film is formed, and the scraping off is performed by moving it in the longitudinal direction of the groove at 5 cm/sec. By the scraping off, in the coating film that is adhered on the area having no grooves, the surplus part thereof is removed and the flatness of the coating film is improved. Next, it is pre-baked on a hot plate under the conditions of 300° C./N2/10 minutes to dry the coating film. After that, by oxidizing the dried film in a thermal diffusion furnace under the conditions of 300° C./80% steam atmosphere/1 hour, it is replaced with a silica film, followed by annealing under the conditions of 850° C./N2/60 minutes, and a cured film is obtained.

After that, for the cross section of the patterned substrate returned to room temperature, using an electron microscope (Regulus 8230 manufactured by Hitachi High-Tech Fielding), the film thickness difference between the area having grooves and the area having no grooves is measured, and whether cracks are occurred or not is observed.

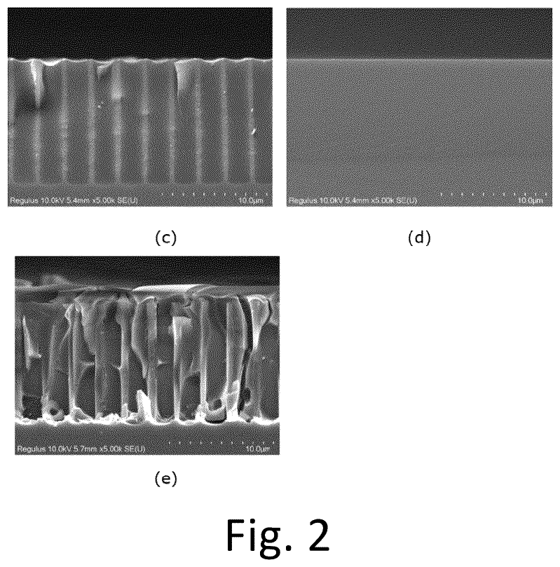

FIG. 2(c) is an electron micrograph photograph of the area having grooves after curing in Example 1, and FIG. 2(d) is that of the area having no grooves.

### Example 3

Using Composition C, it is spin-coated on a silicon wafer having the same pattern as above at a rotational speed of 100 rpm to form a coating film. After the scraping off is performed in the same manner as above, pre-baking is carried out on a hot plate under the conditions of 120° C./air atmosphere/180 seconds to dry the coating film. Thereafter, annealing is performed using a thermal diffusion furnace under the conditions of 650° C./N2/60 minutes to obtain a cured film.

In the same way as above, the film thickness difference between the area having grooves and the areas having no groove is measured, and whether cracks are occurred or not is observed.

### Examples 4 to 8

Except that the force for pressing the separation member against the silicon wafer coated with the composition is changed as shown in Table 1, the film thickness difference between the area having grooves and the area having no grooves is measured and whether cracks are occurred or not is observed in the same manner as in Examples 1 and 2.

### Comparative Examples 1 and 2

Compositions A and B are each dropped on a silicon wafer having the same pattern as above and spin-coated at a rotation speed of 100 rpm to form a coating film. Pre-baking is performed on a hot plate under the conditions of 300° C./N2/10 minutes to dry the coating film. Thereafter, the coating film is replaced with a silica film by oxidizing the coating film at 300° C./80% steam atmosphere/1 hour using a thermal diffusion furnace, followed by annealing at 850° C./N2/60 minutes to obtain a cured film. In the same manner as in Examples 1 and 2, the film thickness difference between the area having grooves and the area having no grooves is measured and whether cracks are occurred or not is observed.

FIG. 2(e) is an electron micrograph photograph of the area having grooves after curing in Comparative Example 1.

### Comparative Example 3

Composition C is dropped on a silicon wafer having the same pattern as above and spin-coated at a rotational speed of 100 rpm to obtain a coating film. Pre-baking is performed on a hot plate under the conditions of 120° C./air atmosphere/180 seconds to dry the coating film. Thereafter, annealing is performed at 650° C./N2/60 minutes using a thermal diffusion furnace to obtain a cured film. In the same manner as in Examples 1 and 2, the film thickness difference between the area having grooves and the area having no grooves is measured and whether cracks are occurred or not is observed.

### Measurement of Elastic Modulus

The elastic modulus of the composition coating film before and after curing is measured using a Nanoindenter ENT-2100 (Elionix). The elastic modulus of before curing is that of the composition coating film before prebaking, and the elastic modulus of after curing is that of the film after annealing.

The elastic modulus is measured in the area having no grooves.

In Comparative Examples 1 to 3, the elastic modulus after curing cannot be measured due to the generation of cracks.

The results of Examples 1 to 8 and Comparative Examples 1 to 3 are summarized in Table 1.

TABLE 1

| | | | | Film | | | |
|---|---|---|---|---|---|---|---|
| | | | Down | thickness | Elastic modulus (GPa) | | |
| | | | force | difference | Before | After | |
| | | Composition | (N) | (μm) | curing | curing | Cracks |
| Example | 1 | Polysilazane-containing | 9.8 | 0.0 | 3.0 | 76 | No |
| | | composition A | | | | | |
| | 2 | Polycarbosilazane- | 9.8 | 0.0 | 3.5 | 68 | No |
| | | containing composition B | | | | | |
| | 3 | Polysiloxane-containing | 9.8 | 0.0 | 2.4 | 10 | No |
| | | composition C | | | | | |
| | 4 | Polysilazane-containing | 7.8 | 0.1 | 3.0 | 76 | No |
| | | composition A | | | | | |
| | 5 | Polysilazane-containing | 2.0 | 0.7 | 3.0 | 76 | No |
| | | composition A | | | | | |
| | 6 | Polycarbosilazane- | 4.9 | 0.3 | 3.5 | 68 | No |
| | | containing composition B | | | | | |
| | 7 | Polysiloxane-containing | 2.0 | 0.6 | 2.4 | 10 | No |
| | | composition C | | | | | |
| | 8 | Polysiloxazane- | 9.8 | 0.0 | 3.2 | 72 | No |
| | | containing composition D | | | | | |
| Comparative | 1 | Polysilazane-containing | — | 6.8 | 3.0 | NA | Yes |
| Ex- | | composition A | | | | | |
| ample | 2 | Polycarbosilazane- | — | 7.2 | 3.5 | NA | Yes |
| | | containing composition B | | | | | |
| | 3 | Polysiloxane-containing | — | 6.6 | 2.4 | NA | Yes |
| | | composition C | | | | | |

Explanation of symbols:
1. substrate having grooves
2. composition layer
3. film thickness difference

1. A method for manufacturing a processed substrate comprising the following steps:
(a) applying a cured film forming composition on a substrate having grooves in an amount sufficient to fill grooves to form a composition layer;
(b) removing the surplus part from the composition layer by scraping off using a separation member to form a substrate surface with improved flatness; and
(c) heating the substrate to cure the composition layer in which the surplus part is removed.

2. The method according to claim 1, wherein the cured film forming composition comprises a silicon-containing polymer selected from the group consisting of polysilazane, polycarbosilazane, polysiloxane and polysiloxazane.

3. The method according to claim 2, wherein the silicon-containing polymer has a mass average molecular weight of 1,000 to 30,000.

4. The method according to claim 2, wherein the content of the silicon-containing polymer is 10 to 100 mass % based on the total amount of the cured film forming composition.

5. The method according to claim 1, wherein the cured film forming composition comprises a solvent.

6. The method according to claim 1, wherein the viscosity as measured by a capillary viscometer at 25° C. of the cured film forming composition is 1.30 to 1.60 mPa·s.

7. The method according to claim 1, which does not contain a step of heating the substrate on which the composition layer is formed at 100° C. or higher before step (b).

8. The method according to claim 1, wherein the heating in step (c) is performed at 300 to 1,000° C.

9. The method according to claim 1, wherein the elastic modulus of the composition layer in which the surplus part is removed in step (b) is 0.5 to 4.5 GPa.

10. The method according to claim 1, wherein the elastic modulus of the cured composition layer in step (c) is 8.0 to 80 GPa.

11. The method according to claim 1, further comprising a step of chemical mechanical polishing after step (c).

12. A method for manufacturing an electronic device, comprising the method according to claim 1.
